(19) United States
(12) Patent Application Publication
(10) Pub. No.: US 2024/0014053 A1
(43) Pub. Date: Jan. 11, 2024

(54) CHARGED-PARTICLE INSPECTION APPARATUS

(71) Applicant: ASML Netherlands B.V., Veldhoven (NL)

(72) Inventors: Dongchi YU, San Jose, CA (US); Erheng WANG, San Jose, CA (US)

(73) Assignee: ASML Netherlands B.V., Veldhoven (NL)

(21) Appl. No.: 18/021,537

(22) PCT Filed: Aug. 16, 2021
(86) PCT No.: PCT/EP2021/072691

§ 371 Date: Feb. 15, 2023

Related U.S. Application Data
(60) Provisional application No. 63/068,824, filed on Aug. 21, 2020.

(51) Int. Cl. H01L 21/67; H01J 37/32; H01L 21/677

(52) U.S. Cl. CPC H01L 21/67201; H01J 37/32449; H01L 21/67742; H01J 37/32981

(57) ABSTRACT

A load-lock system may include a chamber enclosing a supporting structure configured to support a wafer; a gas vent arranged at a ceiling of the chamber and configured to vent gas into the chamber with a flow rate of at least twenty normal liters per minute; and a plate fixed to the ceiling between the gas vent and the wafer.

### CROSS-REFERENCE TO RELATED APPLICATIONS

This application claims priority of U.S. application 63/068,824 which was filed on Aug. 21, 2020 and which is incorporated herein in its entirety by reference.

### FIELD

The embodiments provided herein disclose a charged-particle inspection apparatus, and more particularly, a charged-particle inspection apparatus including an improved load-lock unit.

### BACKGROUND

When manufacturing semiconductor integrated circuit (IC) chips, pattern defects or uninvited particles (residuals) inevitably appear on a wafer or a mask during fabrication processes, thereby reducing the yield to a great degree. For example, uninvited particles may be troublesome for patterns with smaller critical feature dimensions, which have been adopted to meet the increasingly more advanced performance requirements of IC chips.

Pattern inspection tools with one or more charged particle beams have been used to detect the defects or uninvited particles. These tools typically employ a scanning electron microscope (SEM). In the SEM, a beam of primary electrons having a relatively high energy is decelerated to land on a sample at a relatively low landing energy and is focused to form a probe spot thereon. Due to this focused probe spot of primary electrons, secondary electrons will be generated from the surface. By scanning the probe spot over the sample surface and collecting the secondary electrons, pattern inspection tools may obtain an image of the sample surface.

During operation of an inspection tool, the wafer is typically held by a wafer stage. The inspection tool may comprise a wafer positioning device for positioning the wafer stage and wafer relative to the charged-particle beam. This may be used to position a target area on the wafer, i.e. an area to be inspected, in an operating range of the e-beam.

### SUMMARY

Embodiments of the present disclosure provide systems and apparatuses for charged-particle inspection. In some embodiments, a load-lock system may include a chamber enclosing a supporting structure configured to support a wafer. The load-lock system may also include a gas vent arranged at a ceiling of the chamber and configured to vent gas into the chamber with a flow rate of at least twenty normal liters per minute. The load-lock system may further include a plate fixed to the ceiling between the gas vent and the wafer.

In some embodiments, a charged-particle inspection apparatus may include a load-lock system. The load-lock system may include a chamber enclosing a supporting structure configured to support a wafer. The load-lock system may also include a gas vent arranged at a ceiling of the chamber and configured to vent gas into the chamber with a flow rate of at least twenty normal liters per minute. The load-lock system may further include a plate fixed to the ceiling between the gas vent and the wafer.

In some embodiments, an apparatus for reducing contamination of a wafer in a load-lock system may include a wafer holder configured to support the wafer. The apparatus may also include a chamber. The chamber may include a surface. The chamber may also include a gas vent arranged at the surface and configured to vent gas into the chamber during pressurization of the chamber, wherein a direction of the gas flow is perpendicular to the wafer and the surface. The apparatus may further include a baffle arranged between the wafer and the surface and being substantially parallel to the wafer, wherein the baffle is configured to divert the direction of the gas flow away from the wafer.

### BRIEF DESCRIPTION OF THE DRAWINGS

FIG. 1A is a schematic diagram illustrating an example charged-particle beam inspection system, consistent with embodiments of the present disclosure.

FIG. 1B is a schematic diagram illustrating an example wafer loading sequence in the charged-particle beam inspection system of FIG. 1A, consistent with embodiments of the present disclosure.

FIG. 2 is a schematic diagram illustrating an example electron beam tool, consistent with embodiments of the present disclosure that may be a part of the charged-particle beam inspection system of FIG. 1A.

FIG. 3 is an illustration of an example load-lock system, consistent with embodiments of the present disclosure.

FIG. 4 is an illustration of an enlarged view of a part of the load-lock system of FIG. 3, consistent with embodiments of the present disclosure.

FIG. 5 is an example graphic representation of a relationship between gas speed reduction percentages, plate sizes, and sizes of a gap in the load-lock system of FIG. 3, consistent with embodiments of the present disclosure.

FIG. 6 is an example graphic representation of a relationship between volume increment percentages and sizes of the gap of FIG. 5, consistent with embodiments of the present disclosure.

FIG. 7A illustrates a cross-section view showing flow speeds of a gas flow of a pressurization process in a load-lock system having no particle shield, consistent with embodiments of the present disclosure.

FIG. 7B illustrates a cross-section view showing flow speeds of a gas flow of a pressurization process in the load-lock system of FIG. 3, consistent with embodiments of the present disclosure.

FIG. 8A illustrates a perspective view showing shear velocities on an upper surface of a wafer in a pressurization process in a load-lock system having no particle shield, consistent with embodiments of the present disclosure.

FIG. 8B illustrates a perspective view showing shear velocities on an upper surface of a wafer in a pressurization process in the load-lock system of FIG. 3, consistent with embodiments of the present disclosure.

FIG. 9A is an illustration of an example particle trap for the load-lock system of FIG. 3, consistent with embodiments of the present disclosure.

FIG. 9B illustrates a perspective view showing a region high rates of particle deposition in a gap of the load-lock system of FIG. 9A having, consistent with embodiments of the present disclosure.

### DETAILED DESCRIPTION

Reference will now be made in detail to example embodiments, examples of which are illustrated in the accompanying drawings. The following description refers to the accompanying drawings in which the same numbers in different drawings represent the same or similar elements unless otherwise represented. The implementations set forth in the following description of example embodiments do not represent all implementations consistent with the disclosure. Instead, they are merely examples of apparatuses and methods consistent with aspects related to the subject matter recited in the appended claims. Without limiting the scope of the present disclosure, some embodiments may be described in the context of providing detection systems and detection methods in systems utilizing electron beams (“e-beams”). However, the disclosure is not so limited. Other types of charged-particle beams (e.g., including protons, ions, muons, or any other particle carrying electric charges) may be similarly applied. Furthermore, systems and methods for detection may be used in other imaging systems, such as optical imaging, photon detection, x-ray detection, ion detection, or any system for generating images of surfaces or sub-surface structures using radiation technologies.

Electronic devices are constructed of circuits formed on a piece of semiconductor material called a substrate. The semiconductor material may include, for example, silicon, gallium arsenide, indium phosphide, silicon germanium, or any material having electrical properties between those of a conductor and an insulator. Many circuits may be formed together on the same piece of silicon and are called integrated circuits or ICs. The size of these circuits has decreased dramatically so that many more of them can be fit on the substrate. For example, an IC chip in a smartphone can be as small as a thumbnail and yet may include over 2 billion transistors, the size of each transistor being less than 1/1000th the size of a human hair.

Making these ICs with extremely small structures or components is a complex, time-consuming, and expensive process, often involving hundreds of individual steps. Errors in even one step have the potential to result in defects in the finished IC, rendering it useless. Thus, one goal of the manufacturing process is to avoid such defects to maximize the number of functional ICs made in the process; that is, to improve the overall yield of the process.

One component of improving yield is monitoring the chip-making process to ensure that it is producing a sufficient number of functional integrated circuits. One way to monitor the process is to inspect the chip circuit structures at various stages of their formation. Inspection can be carried out using a scanning charged-particle microscope (“SCPM”). For example, an SCPM may be a scanning electron microscope (SEM). A SCPM can be used to image these extremely small structures, in effect, taking a “picture” of the structures of the wafer. The image can be used to determine if the structure was formed properly in the proper location. If the structure is defective, then the process can be adjusted, so the defect is less likely to recur.

While high process yield is desirable in an IC chip manufacturing facility, it is also essential to maintain a high wafer throughput, defined as the number of wafers processed per hour. High process yields and high wafer throughput can be impacted by the presence of defects, especially when there is operator intervention to review the defects. Thus, high throughput detection and identification of micro and nano-sized defects by inspection tools (e.g., an SCPM) is essential for maintaining high yields and low cost.

The SCPM may inspect a wafer in a main chamber. To ensure a high wafer throughput and a smooth wafer-transferring operation, the pressure in the load-lock chamber is typically adjusted by depressurization (“pumping down”) or pressurization (“venting up”) operations. The “depressurization,” as used herein, may refer to processes or procedures for decreasing gas pressure in an enclosed space (e.g., a chamber), such as by pumping gas out of the enclosed space. The “pressurization,” as used herein that may also be referred to as “re-pressurization,” may refer to processes or procedures for increasing gas pressure in an enclosed space (e.g., a chamber), such as by pumping gas into the enclosed space. Before inspection, the wafer may be loaded (e.g., by a robotic arm) from an atmospheric cleanroom environment into a load-lock chamber of the SCPM. The load-lock chamber may be connected to a pump for depressurization. When the gas pressure in the load-lock chamber is below a first threshold pressure (e.g., much lower than the atmospheric pressure), the wafer may be transferred (e.g., by a robotic arm) into the main chamber. The main chamber may be connected with another pump for depressurizing to an even lower pressure. When the gas pressure in the main chamber is below a second threshold pressure (e.g., 10⁻⁶ torr), the wafer inspection may start. When the inspection ends, the wafer may be transferred from the main chamber to the load-lock chamber. The load-lock chamber may be vented up (e.g., by infilling gas into the load-lock chamber through a gas vent) to a target pressure (e.g., the atmospheric pressure) before the wafer is unloaded to the atmospheric cleanroom environment. For better depressurization and pressurization, the load-lock chamber may use a low-volume design, in which a lower amount of gas can be evacuated and infilled.

One challenge of the low-volume design is that the gas flow is stronger in a smaller space. A strong gas flow may incur significant particle contamination on the wafer surface during the pressurization process, as particles that are on the surface of the chamber or gas inlets are lifted by the airflow and are transferred via the air flow to the surface of the wafer, where they appear as a contaminant on the wafer and potentially impact the functioning of a semiconductor device on the wafer. For example, the gas flow may include undesired particles (e.g., dust) that may be deposited on the wafer surface and the inner surfaces of the load-lock chamber. The particle contamination may be aggravated when the gas flow is perpendicular to the wafer surface, onto which the particles in the gas flow may directly impact. Some existing designs of load-lock chambers may use a particle shield to divert the gas flow, purporting to avoid direct impact of the gas flow onto the wafer surface and reduce the particle contamination. However, the strong gas flow may cause flow disturbances (e.g., circulations) that may induce undesirable migration of particles inside the load-lock chamber. For example, the flow disturbances may carry external particles into the load-lock chamber, which may eventually be deposited on the wafer surface and the inner surfaces of the load-lock chamber. In another example, the flow disturbances may blow away existing particles inside the load-lock chamber, and cause them to be deposited on the wafer surface.

Existing designs of load-lock chambers may use large particle shields with complex geometries, which may impose challenges to a low-volume design. Also, the existing designs may not be optimized for flow paths and flow disturbances inside the load-lock chamber, which may have limitation in reducing flow-induced particle contamination. Further, some existing designs may limit the flow rate of the pressurization operation to minimize flow disturbance, purporting to reduce the risk of flow-induced particle contamination, which, however, may compromise system throughput by such slow pressurization operations.

Embodiments of the present disclosure may provide an improved design for load-lock chambers. The provided embodiments may include a low-volume (e.g., below 5 liters) chamber design that has a compact vertical layout. The low-volume design may include a gas vent in the ceiling to accommodate the compact vertical layout, which may vent gas into the load-lock chamber at a high flow rate (e.g., over 20 normal liters per minute). Due to the ceiling-mounted gas vent, the gas flow may enter the load-lock chamber at a direction perpendicular to the wafer. To reduce flow-induced particle contamination, the provided embodiments may include a plate fixed to the ceiling of the load-lock chamber, in which the plate may be between the gas vent and the wafer. The space between the ceiling and the plate and the space between the plate and the wafer may be optimized to reduce flow disturbances while not compromising the low-volume design. By the low-volume design and the high flow rate, the pressurization operation may be completed in a shorter time (e.g., lowered from 30 seconds to 15 seconds) to increase throughput, and an effective overpressure operation of the load lock can be carried out. By the optimized plate, the flow-induced particle contamination may be minimized.

Relative dimensions of components in drawings may be exaggerated for clarity. Within the following description of drawings, the same or like reference numbers refer to the same or like components or entities, and only the differences with respect to the individual embodiments are described.

As used herein, unless specifically stated otherwise, the term “or” encompasses all possible combinations, except where infeasible. For example, if it is stated that a component may include A or B, then, unless specifically stated otherwise or infeasible, the component may include A, or B, or A and B. As a second example, if it is stated that a component may include A, B, or C, then, unless specifically stated otherwise or infeasible, the component may include A, or B, or C, or A and B, or A and C, or B and C, or A and B and C.

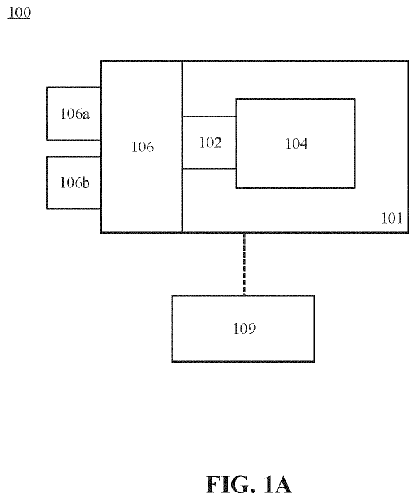

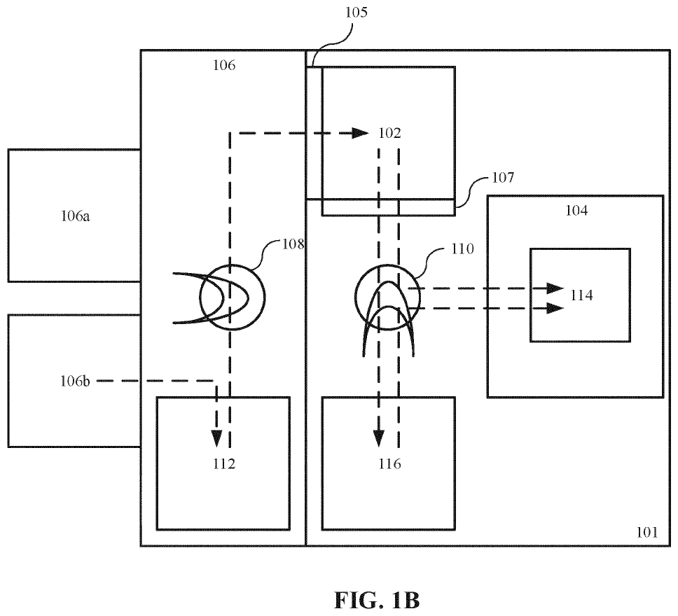

FIG. 1A illustrates an example charged-particle beam inspection system 100 consistent with embodiments of the present disclosure. system 100 may be used for imaging. As shown in FIG. 1A, system 100 includes a main chamber 101, a load-lock chamber 102, a beam tool 104, and an equipment front end module (EFEM) 106. Beam tool 104 is located within main chamber 101 and may be a single-beam system or a multi-beam system. EFEM 106 includes loading ports 106a and 106b. EFEM 106 may include additional loading port(s). Loading ports 106a and 106b may receive wafer front opening unified pods (FOUPs) that contain wafers (e.g., semiconductor wafers or wafers made of other material(s)) or samples to be inspected (wafers and samples may be used interchangeably). A “lot” is a plurality of wafers that may be loaded for processing as a batch. One or more robotic arms (not shown in FIG. 1A) in EFEM 106 may transport the wafers to load-lock chamber 102.

A controller 109 is electronically connected to beam tool 104. Controller 109 may be a computer configured to execute various controls of system 100. While controller 109 is shown in FIG. 1A as being outside of the structure that includes main chamber 101, load-lock chamber 102, and EFEM 106, it is appreciated that controller 109 may be a part of the structure.

In some embodiments, controller 109 may include one or more processors (not shown). A processor may be a generic or specific electronic device capable of manipulating or processing information. For example, the processor may include any combination of any number of a central processing unit (or “CPU”), a graphics processing unit (or “GPU”), an optical processor, a programmable logic controllers, a microcontroller, a microprocessor, a digital signal processor, an intellectual property (IP) core, a Programmable Logic Array (PLA), a Programmable Array Logic (PAL), a Generic Array Logic (GAL), a Complex Programmable Logic Device (CPLD), a Field-Programmable Gate Array (FPGA), a System On Chip (SoC), an Application-Specific Integrated Circuit (ASIC), and any type circuit capable of data processing. The processor may also be a virtual processor that includes one or more processors distributed across multiple machines or devices coupled via a network.

In some embodiments, controller 109 may further include one or more memories (not shown). A memory may be a generic or specific electronic device capable of storing codes and data accessible by the processor (e.g., via a bus). For example, the memory may include any combination of any number of a random-access memory (RAM), a read-only memory (ROM), an optical disc, a magnetic disk, a hard drive, a solid-state drive, a flash drive, a security digital (SD) card, a memory stick, a compact flash (CF) card, or any type of storage device. The codes may include an operating system (OS) and one or more application programs (or “apps”) for specific tasks. The memory may also be a virtual memory that includes one or more memories distributed across multiple machines or devices coupled via a network.

FIG. 1B is a schematic diagram illustrating an example wafer loading sequence in system 100 of FIG. 1A, consistent with embodiments of the present disclosure. In some embodiments, charged-particle beam inspection system 100 may include a robot arm 108 located in EFEM 106 and a robot arm 110 located in main chamber 101. Load-lock chamber 102 may be attached to EFEM 106 via a gate valve 105, and may be attached to main chamber 101 with a gate valve 107. In some embodiments, EFEM 106 may also include a pre-aligner 112 configured to position a wafer accurately before transporting the wafer to load-lock chamber 102.

In some embodiments, loading ports 106a and 106b may receive FOUPs. Robot arm 108 in EFEM 106 may transport the wafers from any of the loading ports 106a or 106b to pre-aligner 112 for assisting with the positioning. Pre-aligner 112 may use mechanical or optical aligning methods to position the wafers. After pre-alignment, robot arm 108 may transport the wafers to load-lock chamber 102 via gate valve 105.

Load-lock chamber 102 may include a sample holder (e.g., a supporting structure, not shown) that can hold one or more wafers. After the wafers are transported to load-lock chamber 102, a load-lock vacuum pump (not shown) may remove gas molecules in load-lock chamber 102 to reach a first pressure below the atmospheric pressure. After reaching the first pressure, a robot arm 110 may transport the wafer via gate valve 107 from load-lock chamber 102 to a wafer stage 114 of beam tool 104 in main chamber 101. Main chamber 101 is connected to a main chamber vacuum pump system (not shown), which may remove gas molecules in main chamber 101 to reach a second pressure below the first pressure. After reaching the second pressure, the wafer may be subject to inspection by beam tool 104.

In some embodiments, main chamber 101 may include a parking station 116 configured to temporarily store a wafer before inspection. For example, when the inspection of a first wafer is completed, the first wafer may be unloaded from wafer stage 114, and then a robot arm 110 may transport a second wafer from parking station 116 to wafer stage 114. Afterwards, robot arm 110 may transport a third wafer from load-lock chamber 102 to parking station 116 to store the third wafer temporarily until the inspection for the second wafer is finished.

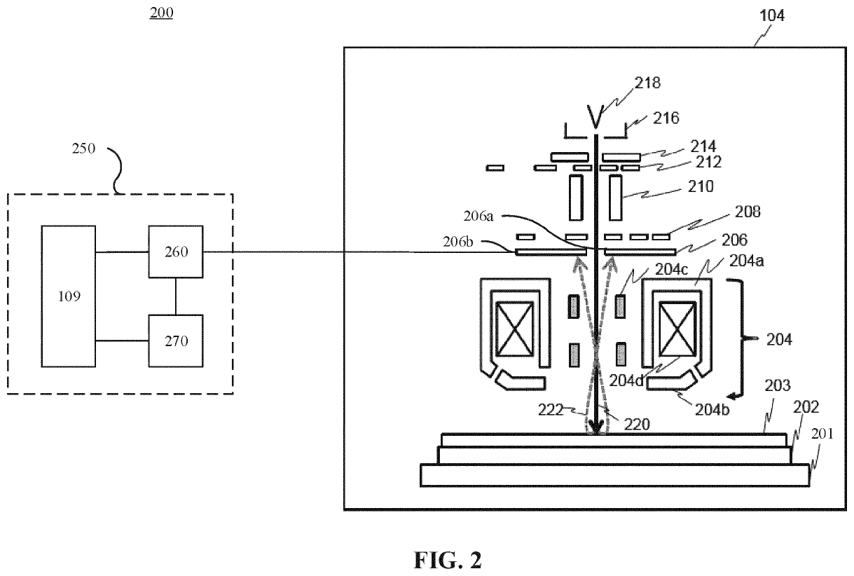

FIG. 2 illustrates an example imaging system 200 according to embodiments of the present disclosure. Electron beam tool 104 of FIG. 2 may be configured for use in system 100. Electron beam tool 104 may be a single beam apparatus or a multi-beam apparatus. As shown in FIG. 2, electron beam tool 104 includes a motorized sample stage 201, and a wafer holder 202 supported by motorized sample stage 201 to hold a wafer 203 to be inspected. Electron beam tool 104 further includes an objective lens assembly 204, an electron detector 206 (which includes electron sensor surfaces 206a and 206b), an objective aperture 208, a condenser lens 210, a beam limit aperture 212, a gun aperture 214, an anode 216, and a cathode 218. Objective lens assembly 204, in some embodiments, may include a modified swing objective retarding immersion lens (SORIL), which includes a pole piece 204a, a control electrode 204b, a deflector 204c, and an exciting coil 204d. Electron beam tool 104 may additionally include an Energy Dispersive X-ray Spectrometer (EDS) detector (not shown) to characterize the materials on wafer 203.

A primary electron beam 220 is emitted from cathode 218 by applying an acceleration voltage between anode 216 and cathode 218. Primary electron beam 220 passes through gun aperture 214 and beam limit aperture 212, both of which may determine the size of electron beam entering condenser lens 210, which resides below beam limit aperture 212. Condenser lens 210 focuses primary electron beam 220 before the beam enters objective aperture 208 to set the size of the electron beam before entering objective lens assembly 204. Deflector 204c deflects primary electron beam 220 to facilitate beam scanning on the wafer. For example, in a scanning process, deflector 204c may be controlled to deflect primary electron beam 220 sequentially onto different locations of top surface of wafer 203 at different time points, to provide data for image reconstruction for different parts of wafer 203. Moreover, deflector 204c may also be controlled to deflect primary electron beam 220 onto different sides of wafer 203 at a particular location, at different time points, to provide data for stereo image reconstruction of the wafer structure at that location. Further, in some embodiments, anode 216 and cathode 218 may generate multiple primary electron beams 220, and electron beam tool 104 may include a plurality of deflectors 204c to project the multiple primary electron beams 220 to different parts/sides of the wafer at the same time, to provide data for image reconstruction for different parts of wafer 203.

Exciting coil 204d and pole piece 204a generate a magnetic field that begins at one end of pole piece 204a and terminates at the other end of pole piece 204a. A part of wafer 203 being scanned by primary electron beam 220 may be immersed in the magnetic field and may be electrically charged, which, in turn, creates an electric field. The electric field reduces the energy of impinging primary electron beam 220 near the surface of wafer 203 before it collides with wafer 203. Control electrode 204b, being electrically isolated from pole piece 204a, controls an electric field on wafer 203 to prevent micro-arching of wafer 203 and to ensure proper beam focus.

A secondary electron beam 222 may be emitted from the part of wafer 203 upon receiving primary electron beam 220. Secondary electron beam 222 may form a beam spot on sensor surfaces 206a and 206b of electron detector 206. Electron detector 206 may generate a signal (e.g., a voltage, a current, or any signal indicative of an electrical property). that represents an intensity of the beam spot and provide the signal to an image processing system 250. The intensity of secondary electron beam 222, and the resultant beam spot, may vary according to the external or internal structure of wafer 203. Moreover, as discussed above, primary electron beam 220 may be projected onto different locations of the top surface of the wafer or different sides of the wafer at a particular location, to generate secondary electron beams 222 (and the resultant beam spot) of different intensities. Therefore, by mapping the intensities of the beam spots with the locations of wafer 203, the processing system may reconstruct an image that reflects the internal or surface structures of wafer 203.

Imaging system 200 may be used for inspecting a wafer 203 on motorized sample stage 201 and includes an electron beam tool 104, as discussed above Imaging system 200 may also include an image processing system 250 that includes an image acquirer 260, storage 270, and controller 109. Image acquirer 260 may include one or more processors. For example, image acquirer 260 may include a computer, server, mainframe host, terminals, personal computer, any kind of mobile computing devices, and the like, or a combination thereof. Image acquirer 260 may connect with a detector 206 of electron beam tool 104 through a medium such as an electrical conductor, optical fiber cable, portable storage media, IR, Bluetooth, internet, wireless network, wireless radio, or a combination thereof. Image acquirer 260 may receive a signal from detector 206 and may construct an image. Image acquirer 260 may thus acquire images of wafer 203. Image acquirer 260 may also perform various post-processing functions, such as generating contours, superimposing indicators on an acquired image, and the like. Image acquirer 260 may perform adjustments of brightness and contrast, or any image properties. of acquired images. Storage 270 may be a storage medium such as a hard disk, cloud storage, random access memory (RAM), other types of computer readable memory, and the like. Storage 270 may be coupled with image acquirer 260 and may be used for saving scanned raw image data as original images, and post-processed images. Image acquirer 260 and storage 270 may be connected to controller 109. In some embodiments, image acquirer 260, storage 270, and controller 109 may be integrated together as one control unit.

In some embodiments, image acquirer 260 may acquire one or more images of a sample based on an imaging signal received from detector 206. An imaging signal may correspond to a scanning operation for conducting charged particle imaging. An acquired image may be a single image including a plurality of imaging areas. The single image may be stored in storage 270. The single image may be an original image that may be divided into a plurality of regions. Each of the regions may include one imaging area containing a feature of wafer 203.

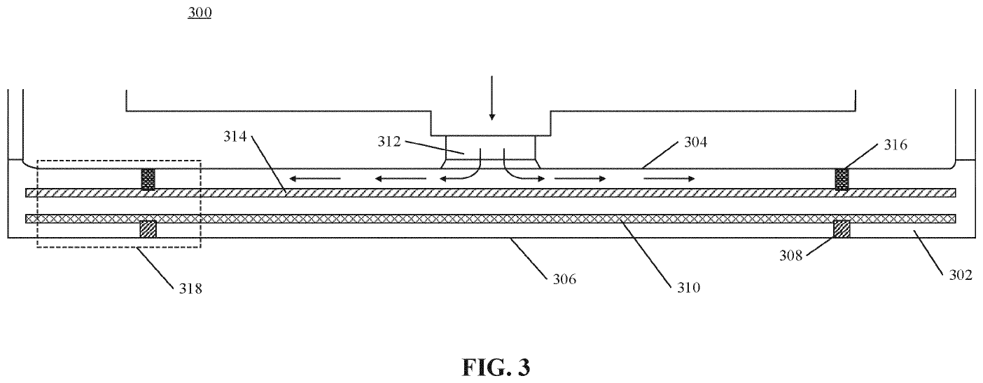

FIG. 3 is an illustration of an example load-lock system 300, consistent with embodiments of the present disclosure. In FIG. 3, load-lock system 300 includes a chamber 302 that includes a ceiling 304 and a floor 306. In some embodiments, chamber 302 may have a cylindrical shape. Chamber 302 may enclose one or more supporting structures (e.g., wafer seats) arranged on floor 306, including supporting structure 308. The supporting structures may be used to support a wafer 310. It is noted that, although wafer 310 is shown in FIG. 3 for ease of explanation, load-lock system 300 may or may not include wafer 310. Load-lock system 300 may further include a gas vent 312 at ceiling 304. Gas vent 312 may be used to vent gas into chamber 302 (e.g., in a pressurization operation) with a high flow rate. For example, the flow rate may be at least 20 normal liters per minute (NL/min). A normal liter is one liter of gas at a pressure of one atmosphere and at a standard temperature (e.g., 0° C. or 20° C.). In some embodiments, the flow rate may be higher than 20 NL/min (e.g., 40 NL/min or 60 NL/min). Load-lock system 300 may further include a plate 314 fixed to ceiling 304 between gas vent 312 and wafer 310. As an example, as shown in FIG. 3, load-lock system 300 may include one or more suspending structures (including suspending structure 316) fixed to ceiling 304, and the one or more suspending structures (including suspending structure 316) may be used to fix plate 314. In some embodiments, load-lock system 300 may further include a gas supply system (e.g., a pump, a gas reservoir, or any system for providing gas, not shown in FIG. 3) that couples to gas vent 312 for extracting, filling, or regulating gas.

In some embodiments, load-lock system 300 may use a low-volume design. For example, a volume of chamber 302 may not exceed five liters. In some embodiments, load-lock system 300 may use a compact vertical layout to accommodate the low-volume design. For example, as shown in FIG. 3, chamber 302 may have a height up to 35 millimeters (mm) between ceiling 304 and floor 306. In an embodiment, the height of chamber 302 may be 30 to 34 mm.

In some embodiments, gas vent 312 may be arranged at a center of ceiling 304. For example, when chamber 302 has a cylindrical shape, ceiling 304 may be substantially a circle, and gas vent 312 may be arranged at the circular center of ceiling 304. In some embodiments, gas vent 312 may cause a direction of a gas flow through gas vent 312 to be perpendicular to plate 314, as indicated by the arrows in FIG. 3. In some embodiments, the gas may include nitrogen, helium, hydrogen, argon, carbon dioxide, or compressed air.

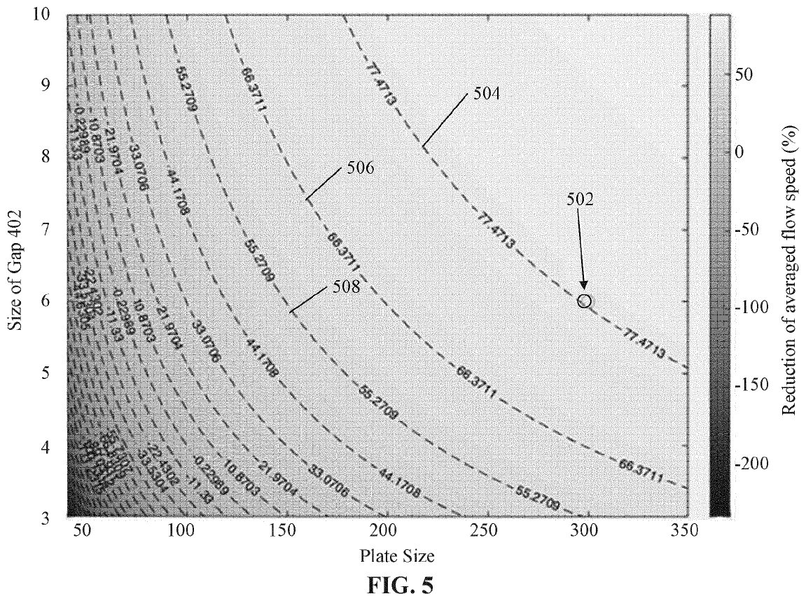

Plate 314 may be used to restrain, divert, or regulate a gas flow entering chamber 302 through gas vent 312. Plate 314 may be used as a particle shield for reducing exposure of wafer 310 to a potentially contaminating environment (e.g., an atmospheric environment having airborne dust suspended above wafer 310), such as due to flow-induced particle contamination or gravity-induced deposition. In some embodiments, as shown in FIG. 3, plate 314 may be substantially parallel (e.g., with a tilted angle of at most 2 degrees measured from the center of plate 314) to ceiling 304 and wafer 310. In some embodiments, plate 314 may have the same shape with wafer 310. For example, if wafer 310 has a circle shape, plate 314 may also be in a circle shape. In some embodiments, plate 314 may be centered at gas vent 312. For example, when plate 314 is in a circular shape, the circular center of plate 314 may be aligned (e.g., vertically aligned) at gas vent 312. In some embodiments, plate 314 may have substantially the same size with wafer 310. For example, margins of plate 314 may be off from margins of wafer 310 within a positive or negative error tolerance (e.g., 6 mm). In another example, if wafer 310 is round, the diameter of plate 314 may be longer than, shorter than, or exactly the same as the diameter of wafer 310 within a positive or negative error tolerance (e.g., 2% of the diameter of wafer 310). For example, if wafer 310 is round and has a diameter of 300 mm, plate 314 may also be round and have a diameter of 300±6 mm. In some embodiments, the size of plate 314 may have a predetermined size that is independent from the size of wafer 310. For example, plate 314 may be round and have a predetermined diameter with a predetermined tolerance (e.g., 300±6 mm), while wafer 310 may be round and have a diameter smaller than the predetermined diameter (e.g., 100 mm, 125 mm, 150 mm, 200 mm, or any length shorter than 300 mm). It should be noted that the size and shape of plate 314 may be determined based on effectiveness of gas speed reduction (that will be described in association with FIG. 5) and are not limited to the above-described examples. In some embodiments, plate 314 may be a metal plate. For example, plate 314 may be made of stainless steel.

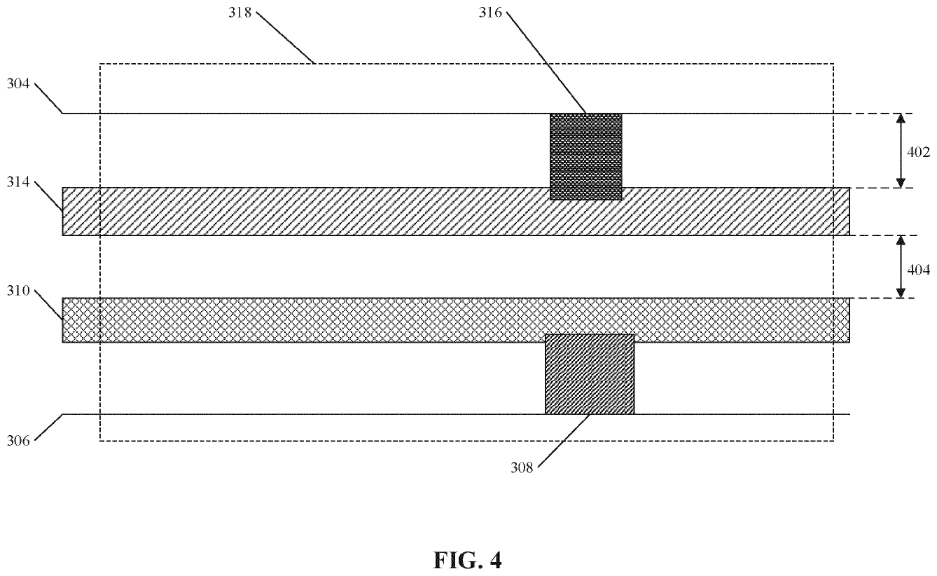

In some embodiments, the arrangement of plate 314 may be optimized to balance between efficiency of depressurization (e.g., extracting gas out of chamber 302) of chamber 302 and minimization of the volume of chamber 302. FIG. 4 is an illustration of an enlarged view of part 318 of load-lock system 300, consistent with embodiments of the present disclosure. As shown in FIG. 4, a gap 402 is between ceiling 304 and an upper surface of plate 314, and a gap 404 is between a lower surface of plate 314 and an upper surface of wafer 310. In some embodiments, gap 402 may be 3 to 10 mm. In some embodiments, gap 402 may be substantially 6 mm (e.g., 6±0.2 mm). In some embodiments, gap 404 may be 5 to 10 mm. In some embodiments, gap 404 may be substantially 5 mm (e.g., 5±0.2 mm).

As shown in FIGS. 3-4, load-lock system 300 may use a low-volume design with a compact vertical layout. Plate 314 may be substantially the same size of wafer 310 such that wafer 310 may be shielded from a gas flow entering chamber 302 via gas vent 312 in a direction perpendicular to wafer 310. Although the gas flow may have a high flow rate (e.g., at least 20 NL/min), the speed of the gas flow may be sufficiently slowed down by plate 314 as configured before reaching wafer 310, and may steadily fill up chamber 302 by travelling over an edge of plate 314. By doing so, flow disturbances (e.g., flow circulations) may be suppressed inside chamber 302, and flow-induced particle contamination to wafer 310 may be reduced or minimized, while the wafer throughput may be maintained at a high level because time consumption for pressurization of depressurization may be greatly reduced (e.g., below 30 seconds, such as 15 seconds) by the low volume of chamber 302 and the high flow rate of the gas flow. Further, the compact vertical layout may facilitate load-lock system 300 to be more easily integrated into a charged-particle inspection apparatus (e.g., charged-particle beam inspection system 100).

Gap 402 of FIG. 4 may be optimized. In some embodiments, gap 402 may be configured to be at least 3 mm to avoid compromising depressurization (e.g., “pumping down”) efficiency while ensuring the effectiveness of slowing down the incoming gas flow. FIG. 5 is an example graphic representation of a relationship between gas speed reduction percentages, plate sizes, and sizes of gap 402, consistent with embodiments of the present disclosure. In FIG. 5, the horizontal axis represents sizes of plate 314, the vertical axis on the left represents sizes of gap 402, the vertical legend on the right represents grayscales corresponding to reduction percentages of averaged flow speeds, and the grayscale colors in the graph represent reduction percentages of averaged flow speeds of a gas flow entering chamber 302 via gas vent 312. The positive reduction percentages indicate that the averaged flow speeds of the gas flow are decreased by plate 314, and the negative reduction percentages indicate that the averaged flow speeds of the gas flow are actually increased by plate 314 due to aerodynamics. As shown in the legend, from bright colors to dark colors, the grayscales represent the reduction percentages varying from positive to negative, respectively. The dashed lines on top of the grayscale colors in FIG. 5 represent equal-percentage contours, including contours 504 (representing reduction percentage of 77.4713%), 506 (representing reduction percentage of 66.3711%), and 508 (representing reduction percentage of 55.2709%). For example, a point in contour 504 may represent a combination of a size of gap 402 and a size of plate 314, and contour 504 may represent that all points (i.e., all corresponding combinations of sizes of gap 402 and sizes of plate 314) in contour 504 may yield a reduction percentage of 77.4713% for the averaged flow speed. All equal-percentage contours in FIG. 5 may have similar representations. Contour 504 includes a point 502, which represents a size (e.g., a height) of gap 402 as 6 mm and a size (e.g., a diameter) of plate 314 as 300 mm. As shown in FIG. 5, in some combinations of the size of gap 402 and the size of plate 314, a reduction percentage for the averaged flow speed may be over 80%.

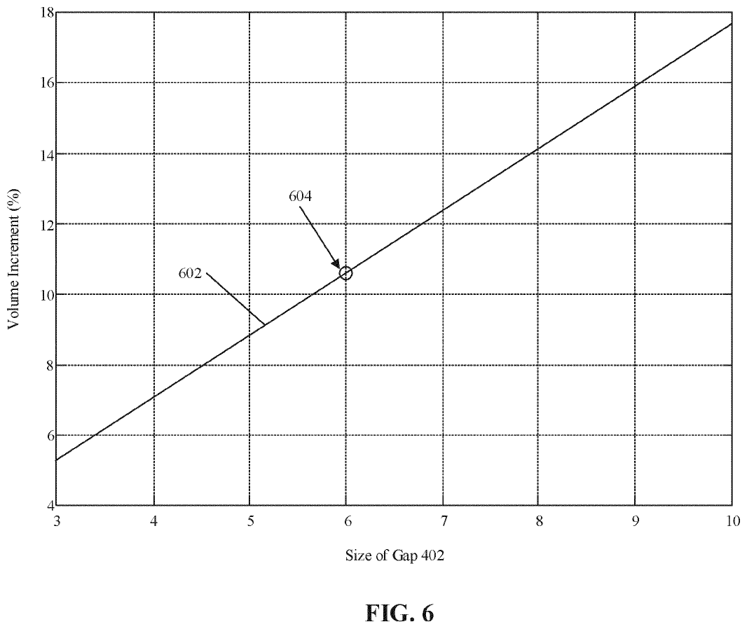

In some embodiments, gap 402 may be configured to be at most 10 mm to avoid substantially enlarging a volume of chamber 302 in FIG. 3. An enlarged volume of chamber 302 may compromise wafer throughput because it may require a longer time for the pressurization (“venting up”) operation in chamber 302. FIG. 6 is an example graphic representation of a relationship between volume increment percentages and sizes of gap 402, consistent with embodiments of the present disclosure. In FIG. 6, the horizontal axis represents sizes of gap 402, and the vertical axis represents increment percentages for a volume of chamber 302 in FIG. 3. As shown in FIG. 6, if a size of gap 402 increases, the volume of chamber 302 also increases along line 602. Line 602 includes a point 604 that corresponds to a 6 mm size (e.g., height) of gap 402. As shown in FIG. 6, the increment of the volume of chamber 302 corresponding to point 604 is around 10.5%.

In some embodiments of load-lock system 300 in FIG. 3, gap 402 and plate 314 may be 6 mm and 300 mm, respectively. As shown in FIGS. 5-6, such a combination may yield a reduction percentage of 77.4713% for the averaged flow speed of the gas flow and a 10.5% increment of the volume of chamber 302. Such a combination may achieve a great balance among depressurization efficiency, effectiveness of slowing down the incoming gas flow, suppression of flow-induced particle contamination, and a low volume of chamber 302.

Gap 404 of FIG. 4 may also be optimized. In some embodiments, gap 404 may be configured to be at least 5 mm to ensure sufficient working space for a robot arm (e.g., robot arm 110 in FIG. 1B) to transfer wafer 310 to and from chamber 302 among other parts of a charged-particle inspection apparatus (e.g., charged-particle beam inspection system 100), such as wafer stage 114 or parking station 116 in FIG. 1B. In some embodiments, gap 404 may be configured to be at most 10 mm to avoid substantially enlarging a volume of chamber 302 in FIG. 3. In an embodiment of load-lock system 300 in FIG. 3, gap 404 may be 5 mm, which may achieve a great balance among depressurization efficiency, effectiveness of slowing down the incoming gas flow, suppression of flow-induced particle contamination, and a low volume of chamber 302.

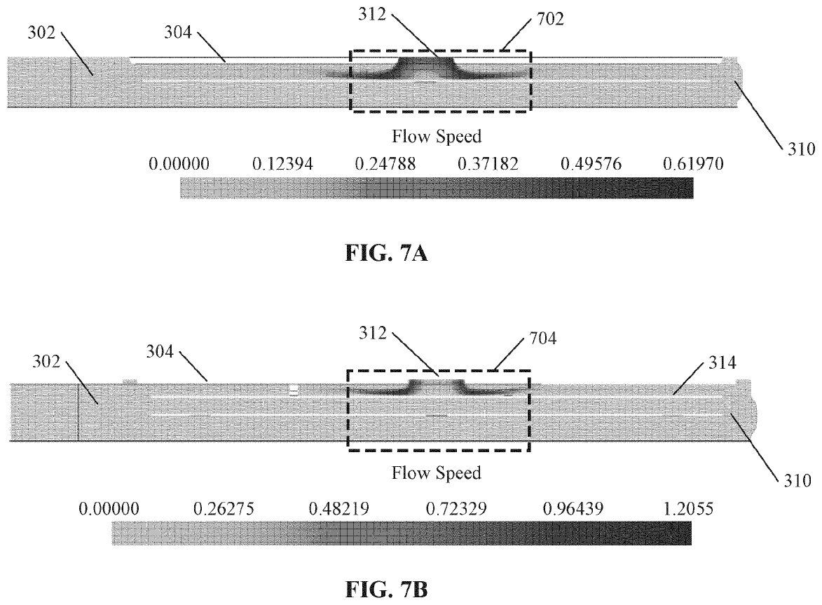

In some embodiments, with optimized configuration, plate 314 of FIG. 3 may shield wafer 310 from direct impact of airborne particles and substantially reduce a flow speed of a gas flow in chamber 302, while not compromising time durations for pressurizing chamber 302. FIG. 7A illustrates a cross-section view showing flow speeds of a gas flow of a pressurization process in a load-lock system having no particle shield for wafer 310, consistent with embodiments of the present disclosure. FIG. 7B illustrates a cross-section view showing flow speeds of a gas flow of a pressurization process in load-lock system 300 having plate 314 for wafer 310, consistent with embodiments of the present disclosure. The legends at the bottoms of FIGS. 7A-7B represent grayscales corresponding to different flow speeds. As shown in the legends, the darker the grayscales are, the higher the flow speeds may be, and the brighter the grayscales are, the lower the flow speeds may be. It should be noted that the numbers representing flow speeds in the legends of FIGS. 7A-7B are for examples only, and this disclosure does not intend to limit them as such. FIGS. 7A-7B may be graphical representations of computational fluid dynamics simulations.

As shown in FIGS. 7A-7B, a high-flow rate (e.g., at least 20 NL/min) gas flow may enter chamber 302 via gas vent 312. The difference between FIGS. 7A and 7B is that the load-lock system (e.g., load-lock system 300 as shown in FIGS. 3-4) in FIG. 7B includes a plate (e.g., plate 314) above wafer 310 as a particle shield. The gas flow may fill up chamber 302 by traveling over an edge of wafer 310 (as shown in FIG. 7A) or an edge of plate 314 (as shown in FIG. 7B).

In FIG. 7A, the gas flow directly impact wafer 310, which may incur significant particle contamination to wafer 310. In contrast, in FIG. 7B, the gas flow is shielded from wafer 310 by plate 314, which may reduce the particle contamination due to direct impact of the gas flow. Also, plate 314 may substantially reduce flow disturbances in chamber 302 during the pressurization process. The grayscale colors in FIGS. 7A-7B represent flow speeds. As shown in regions 702 and 704 in FIGS. 7A-7B, the flow speed in region 704 is significantly lower than the flow speed in region 702 due to plate 314. A lower flow speed may reduce the flow disturbances (e.g., flow circulations) in chamber 302, which, in turn, may reduce particle contamination resulting from particles stirred (e.g., from inner surfaces of chamber 302) by a high-speed gas flow. Also, if there are particles originally attached to the surface of wafer 310, a slower flow speed may reduce the likelihood of stirring up those particles into chamber 302, which, in turn, may reduce cross-contamination to other wafers.

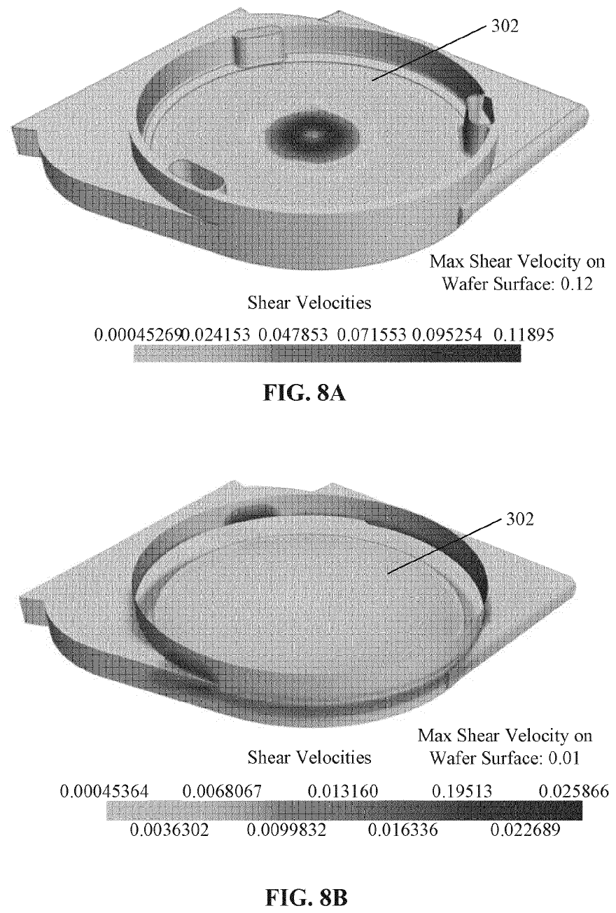

In some embodiments, with optimized configuration, plate 314 of FIG. 3 may reduce a shear velocity on wafer 310. A shear velocity (also referred to as “friction velocity”) may represent a shear stress in a form of velocity units to describe shear-related motion (e.g., diffusion or dispersion of particles) in moving gases or fluids. The shear velocity may depend on shear between layers of a flow. For example, the shear velocity on wafer 310 may be positively correlated with magnitude of flow-induced particle migration in chamber 302. FIG. 8A illustrates a perspective view showing shear velocities on an upper surface of wafer 310 in a pressurization process in a load-lock system having no particle shield for wafer 310, consistent with embodiments of the present disclosure. FIG. 8B illustrates a perspective view showing shear velocities on an upper surface of wafer 310 in a pressurization process in load-lock system 300 having plate 314 for wafer 310, consistent with embodiments of the present disclosure. FIGS. 8A-8B may be graphical representations of computational fluid dynamics simulations. The legends at the bottoms of FIGS. 8A-8B represent grayscales corresponding to different values of the shear velocities. As shown in the legends, the darker the grayscales are, the higher the shear velocities may be, and the brighter the grayscales are, the lower the shear velocities may be. It should be noted that the numbers representing shear velocities in the legends of FIGS. 8A-8B are for examples only, and this disclosure does not intend to limit them as such. Compared with FIG. 8A, FIG. 8B shows significantly lower shear velocities on the upper surface of wafer 310. For example, the maximum shear velocity on the upper surface of wafer 310 in FIG. 8A is 0.12 m/s, while the maximum shear velocity on the upper surface of wafer 310 in FIG. 8B is 0.01 m/s. In some embodiments, the maximum shear velocities on the upper surface of wafer 310 may be reduced by at least 90%.

As shown in FIGS. 8A-8B, plate 314 may reduce the shear velocity, in which resuspension rate of micron-scale (e.g., with sizes up to 10 microns or μm) particles may be significantly suppressed (e.g., to a negligible extent) on inner surfaces of chamber 302 and wafer 310. In some embodiments, without plate 314, particles with sizes over 5 μm may be resuspended from the inner surfaces of chamber 302 and wafer 310, and may cause particle contamination or cross-contamination for wafer 310.

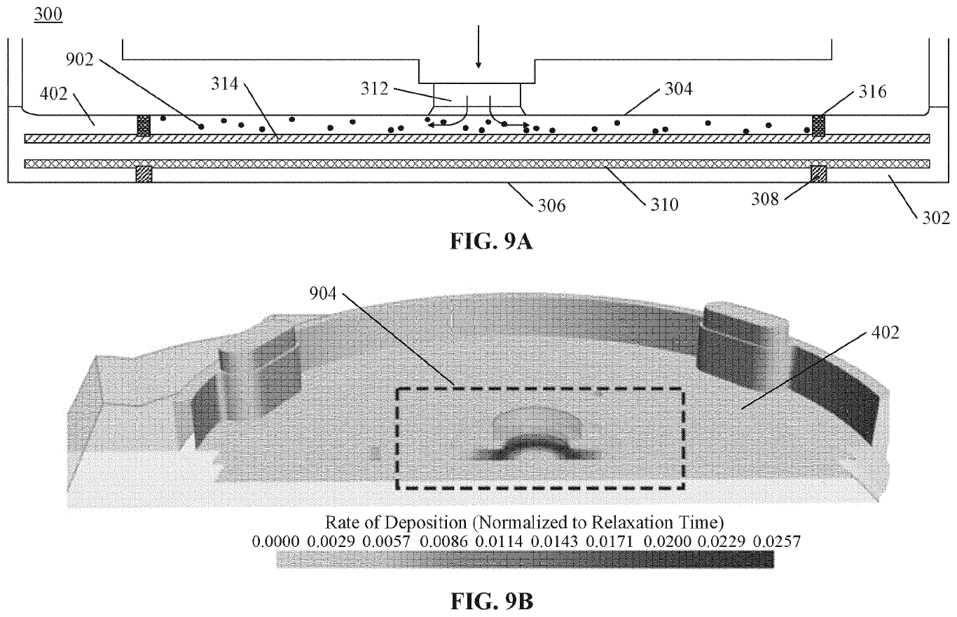

In some embodiments, with optimized configuration, plate 314 of FIG. 3 may trap a significant portion of particles in chamber 302. FIG. 9A is an illustration of an example particle trap for load-lock system 300, consistent with embodiments of the present disclosure. When a high-speed (e.g., at least 20 NL/min) gas flow enters chamber 302 via gas vent 312, it may carry external particles (e.g., dust), including particles 902. The high-speed flow may deposit the external particles to plate 314, and gap 402 may serve as a particle trap that may effectively capture the external particles to reduce the likelihood for the external particles to be diffused to wafer 310.

In some embodiments, even if the gas flow is not filtered (e.g., by a filter upstream to gas vent 312) or chamber 302 is not sufficiently clean (e.g., including internal particles), particles with sizes over 4 μm may still be captured and retained in gap 402. FIG. 9B illustrates a perspective view showing a region 904 of gap 402 having high rates of particle deposition, consistent with embodiments of the present disclosure. FIG. 9B may be a graphical representation of computational fluid dynamics simulations. The rate of deposition (also referred to as “deposition velocity”) in FIG. 9B are normalized with respect to particle properties into normalized relaxation time. The legend at the bottom of FIG. 9B represent grayscales corresponding to different values of the rates of deposition. As shown in the legend, the darker the grayscales are, the higher the rates of deposition may be, and the brighter the grayscales are, the lower the rates of deposition may be. It should be noted that the numbers representing rates of deposition in the legend of FIG. 9B are for examples only, and this disclosure does not intend to limit them as such. As shown in FIG. 9B, due to high rates of particle deposition in region 904, particles with sizes over 4 μm may still be captured and retained in gap 402.

As shown in FIGS. 9A-9B, by such a design and configuration, particle contamination of wafer 310 may be minimized, and robustness of the charged-particle inspection apparatus (e.g., charged-particle beam inspection system 100) may be improved. Because of the improved robustness and the effective protection against particle contamination, in some embodiments, aggressive pressurization (e.g., with a flow rate of at least 40 NL/min, such as 60 NL/min) may be applied without causing noticeable particle contamination. In those cases, the time duration for pressurizing chamber 302 to a threshold pressure (e.g., from 10⁻⁶ torr to 760 torr) may be significantly reduced (e.g., lowered from 30 seconds to 15 seconds).

Aspects of the present disclosure are set out in the following numbered clauses:

1. A load-lock system, comprising:
a chamber enclosing a supporting structure configured to support a wafer;
a gas vent arranged at a ceiling of the chamber and configured to vent gas into the chamber with a flow rate of at least twenty normal liters per minute; and
a plate fixed to the ceiling between the gas vent and the wafer.

2. The load-lock system of clause 1, wherein the plate is substantially parallel to the ceiling and the wafer.

3. The load-lock system of clause 2, wherein a first gap between the plate and the ceiling is three to ten millimeters.

4. The load-lock system of clause 3, wherein the first gap is six millimeters.

5. The load-lock system of any of clauses 2-4, wherein a second gap between the plate and the wafer is five to ten millimeters.

6. The load-lock system of clause 5, wherein the second gap is five millimeters.

7. The load-lock system of any of clauses 1-6, wherein the chamber has a cylindrical shape.

8. The load-lock system of any of clauses 1-7, wherein the chamber has a height up to 35 millimeters between the ceiling and a floor of the chamber.

9. The load-lock system of clause 8, wherein the height is thirty to thirty-four millimeters.

10. The load-lock system of any of clauses 1-9, wherein a volume of the chamber is up to five liters.

11. The load-lock system of any of clauses 1-10, wherein the gas vent is arranged at a center of the ceiling.

12. The load-lock system of any of clauses 1-11, wherein the gas vent is configured to cause a direction of a gas flow through the gas vent to be perpendicular to the plate.

13. The load-lock system of any of clauses 1-12, wherein the gas comprises nitrogen, helium, hydrogen, argon, carbon dioxide, or compressed air.

14. The load-lock system of any of clauses 1-13, wherein the plate is configured to be centered at the gas vent.

15. The load-lock system of any of clauses 1-14, wherein the plate has a shape that is substantially the same as a shape of the wafer.

16. The load-lock system of any of clauses 1-15, wherein the plate has substantially the same size with the wafer.

17. The load-lock system of any of clauses 1-16, wherein the plate is round and has a diameter of 300 millimeters.

18. The load-lock system of any of clauses 1-17, wherein the plate is a metal plate.

19. The load-lock system of any of clauses 1-18, wherein the plate is made of stainless steel.

20. The load-lock system of any of clauses 1-19, further comprising:

a suspending structure fixed to the ceiling, wherein the suspending structure is configured to fix the plate.

21. The load-lock system of any of clauses 1-20, further comprising:

a gas supply system configured to couple to the gas vent.

22. The load-lock system of any of clauses 1-21, wherein a time for venting the gas into the chamber to a threshold pressure is below thirty seconds.

23. The load-lock system of clause 22, wherein the threshold pressure is an atmospheric pressure.

24. The load-lock system of any of clauses 22-23, wherein the time is down to 15 seconds.

25. A charged-particle inspection apparatus, comprising a load-lock system of any of clauses 1-24.

26. An apparatus for reducing contamination of a wafer in a load-lock system, comprising:
a wafer holder configured to support the wafer;
a chamber, comprising:
   a surface; and
   a gas vent arranged at the surface and configured to vent gas into the chamber during pressurization of the chamber, wherein a direction of the gas flow is perpendicular to the wafer and the surface; and
a baffle arranged between the wafer and the surface and being substantially parallel to the wafer, wherein the baffle is configured to divert the direction of the gas flow away from the wafer.

27. The apparatus of clause 26, wherein the gas flow has a flow rate of at least twenty normal liters per minute.

28. The apparatus of any of clauses 26-27, wherein the baffle is substantially parallel to the surface and the wafer.

29. The apparatus of clause 28, wherein a first gap between the baffle and the surface is three to ten millimeters.

30. The apparatus of clause 29, wherein the first gap is substantially six millimeters.

31. The apparatus of any of clauses 28-30, wherein a second gap between the baffle and the wafer is five to ten millimeters.

32. The apparatus of clause 31, wherein the second gap is five millimeters.

33. The apparatus of any of clauses 26-32, wherein the chamber has a cylindrical shape.

34. The apparatus of any of clauses 26-33, wherein the chamber has a height up to 35 millimeters between the surface and a floor of the chamber.

35. The apparatus of clause 34, wherein the height is thirty to thirty-four millimeters.

36. The apparatus of any of clauses 26-35, wherein a volume of the chamber is up to five liters.

37. The apparatus of any of clauses 26-36, wherein the gas vent is arranged at a center of the surface.

38. The apparatus of any of clauses 26-37, wherein the gas vent is configured to cause a direction of a gas flow through the gas vent to be perpendicular to the baffle.

39. The apparatus of any of clauses 26-38, wherein the gas comprises nitrogen, helium, hydrogen, argon, carbon dioxide, or compressed air.

40. The apparatus of any of clauses 26-39, wherein the baffle is configured to be centered at the gas vent.

41. The apparatus of any of clauses 26-40, wherein the baffle has a shape that is substantially the same as a shape of the wafer.

42. The apparatus of any of clauses 26-41, wherein the baffle has substantially the same size with the wafer.

43. The apparatus of any of clauses 26-42, wherein the baffle is round and has a diameter of 300 millimeters.

44. The apparatus of any of clauses 26-43, wherein the baffle is a metal baffle.

45. The apparatus of any of clauses 26-44, wherein the baffle is made of stainless steel.

46. The apparatus of any of clauses 26-45, further comprising:
a suspending structure fixed to the surface, wherein the suspending structure is configured to fix the baffle.

47. The apparatus of any of clauses 26-46, further comprising:
a gas supply system configured to couple to the gas vent.

48. The apparatus of any of clauses 26-47, wherein a time for venting the gas into the chamber to a threshold pressure is below thirty seconds.

49. The apparatus of clause 48, wherein the threshold pressure is an atmospheric pressure.

50. The apparatus of any of clauses 48-49, wherein the time is down to 15 seconds.

The block diagrams in the figures illustrate the architecture, functionality, and operation of possible implementations of systems, methods, and computer hardware or software products according to various example embodiments of the present disclosure. In this regard, each block in a flowchart or block diagram may represent a module, segment, or portion of code, which includes one or more executable instructions for implementing the specified logical functions. It should be understood that in some alternative implementations, functions indicated in a block may occur out of order noted in the figures. For example, two blocks shown in succession may be executed or implemented substantially concurrently, or two blocks may sometimes be executed in reverse order, depending upon the functionality involved. Some blocks may also be omitted. It should also be understood that each block of the block diagrams, and combination of the blocks, may be implemented by special purpose hardware-based systems that perform the specified functions or acts, or by combinations of special purpose hardware and computer instructions.

It will be appreciated that the embodiments of the present disclosure are not limited to the exact construction that has been described above and illustrated in the accompanying drawings, and that various modifications and changes may be made without departing from the scope thereof.

1. A load-lock system, comprising:
a chamber enclosing a supporting structure configured to support a wafer;
a gas vent arranged at a ceiling of the chamber and configured to vent gas into the chamber with a flow rate of at least twenty normal liters per minute; and
a plate fixed to the ceiling between the gas vent and the wafer.

2. The load-lock system of claim 1, wherein the plate is substantially parallel to the ceiling and the wafer.

3. The load-lock system of claim 2, wherein a first gap between the plate and the ceiling is three to ten millimeters.

4. The load-lock system of claim 3, wherein the first gap is six millimeters.

5. The load-lock system of claim 2, wherein a second gap between the plate and the wafer is five to ten millimeters.

6. The load-lock system of claim 5, wherein the second gap is five millimeters.

7. The load-lock system of claim 1, wherein the chamber has a cylindrical shape.

8. The load-lock system of claim 1, wherein the chamber has a height up to 35 millimeters between the ceiling and a floor of the chamber.

9. The load-lock system of claim 8, wherein the height is thirty to thirty-four millimeters.

10. The load-lock system of claim 1, wherein a volume of the chamber is up to five liters.

11. The load-lock system of claim 1, wherein the gas vent is arranged at a center of the ceiling.

12. The load-lock system of claim 1, wherein the gas vent is configured to cause a direction of a gas flow through the gas vent to be perpendicular to the plate.

13. The load-lock system of claim 1, wherein the gas comprises nitrogen, helium, hydrogen, argon, carbon dioxide, or compressed air.

14. The load-lock system of claim 1, wherein the plate is configured to be centered at the gas vent.

15. The load-lock system of claim 1, wherein the plate has a shape that is substantially the same as a shape of the wafer.

16. An apparatus for reducing contamination of a wafer in a load-lock system, comprising:
a wafer holder configured to support the wafer;
a chamber, comprising:
a surface; and
a gas vent arranged at the surface and configured to vent gas into the chamber during pressurization of the chamber, wherein a direction of the gas flow is perpendicular to the wafer and the surface; and
a baffle arranged between the wafer and the surface and being substantially parallel to the wafer, wherein the baffle is configured to divert the direction of the gas flow away from the wafer.

17. The apparatus of claim 16, wherein the baffle is substantially parallel to the surface and the wafer.

18. The apparatus of claim 16, wherein a first gap between the baffle and the surface is three to ten millimeters.

19. The apparatus of claim 16, wherein a second gap between the baffle and the wafer is five to ten millimeters.

20. The apparatus of claim 16, wherein the gas vent is configured to cause a direction of a gas flow through the gas vent to be perpendicular to the baffle.
